(19) United States
(12) Patent Application Publication
(10) Pub. No.: US 2026/0341359 A1
(43) Pub. Date: Oct. 29, 2026

(54) WORD LINE DRIVING CIRCUIT AND SEMICONDUCTOR MEMORY DEVICE INCLUDING THE WORD LINE DRIVING CIRCUIT

(71) Applicant: SK hynix Inc., Icheon-si Gyeonggi-do (KR)

(72) Inventor: Sang Woo YOON, Icheon-si Gyeonggi-do (KR)

(73) Assignee: SK hynix Inc., Icheon-si Gyeonggi-do (KR)

(21) Appl. No.: 19/305,562

(22) Filed: Aug. 20, 2025

(30) Foreign Application Priority Data
Apr. 29, 2025 (KR) 10-2025-0055897

(51) Int. Cl. G11C 16/08; G11C 16/04; G11C 16/28; G11C 16/30

(52) U.S. Cl. CPC G11C 16/08; G11C 16/0483; G11C 16/28; G11C 16/30

(57) ABSTRACT

A word line driving circuit includes an auxiliary driver configured to supply one of a high voltage and a low voltage to a word line activation voltage terminal in response to an auxiliary selection signal, a main driver configured to drive a word line with one of a voltage of the word line activation voltage terminal and the low voltage in response to a main selection signal and drive the word line with the low voltage in response to the auxiliary selection signal, and a voltage discharger configured to drive the word line activation voltage terminal with the low voltage in response to the auxiliary selection signal when a level of the high voltage is determined to be higher than a reference value.

### CROSS-REFERENCE TO RELATED APPLICATION(S)

The present application claims priority under 35 U.S.C. §119(a) to Korean Patent Application No. 10-2025-0055897, filed in the Korean Intellectual Property Office, on April 29, 2025, the entire contents of which application is incorporated herein by reference.

### BACKGROUND

Various embodiments of the present disclosure generally relate to semiconductor memory device, and more particularly, to a word line driving circuit and semiconductor memory device including the word line driving circuit.

Various integrated circuits generate and use not only a power voltage supplied from an external device, but also an internal voltage having different levels from the power voltage. For example, in a semiconductor memory device, a high voltage that is higher than the power voltage is generated internally and used as a voltage to drive a word line.

Operations performed most frequently in a semiconductor memory device include an active operation, which activates a word line at a high voltage level, and a pre-charge operation, which deactivates the word line at a low voltage level again. When the active operation and the pre-charge operation are repeatedly performed, elements of a word line driving circuit that drives the word line may deteriorate.

In accordance with an embodiment of the present disclosure, a word line driving circuit may include: an auxiliary driver configured to supply one of a high voltage and a low voltage to a word line activation voltage terminal in response to an auxiliary selection signal; a main driver configured to drive a word line with one of a voltage of the word line activation voltage terminal and the low voltage in response to a main selection signal and drive the word line with the low voltage in response to the auxiliary selection signal; and a voltage discharger configured to drive the word line activation voltage terminal with the low voltage in response to the auxiliary selection signal when a level of the high voltage is determined to be higher than a reference value.

In accordance with an embodiment of the present disclosure, a semiconductor memory device may include: a plurality of word lines; a high voltage level detector configured to detect when a level of a high voltage is higher than a reference value during an active operation; a decoder circuit configured to decode an address and generate a plurality of main selection signals and a plurality of auxiliary selection signals; and a plurality of word line driving circuits each configured to drive a corresponding one word line according to one of the plurality of main selection signals, one of the plurality of auxiliary selection signals and a detection result of the high voltage level detector.

### BRIEF DESCRIPTION OF THE DRAWINGS

FIG. 1 is a configuration diagram illustrating a word line driving circuit in accordance with an embodiment of the present disclosure.

FIG. 2 is a configuration diagram illustrating a word line driving circuit in accordance with an embodiment of the present disclosure.

FIG. 3 is a configuration diagram illustrating a semiconductor memory device in accordance with an embodiment of the present disclosure.

FIG. 4 is a configuration diagram illustrating an example of a high voltage level detector illustrated in FIG. 3.

FIG. 5 is a configuration diagram illustrating an example of a word line driving circuit illustrated in FIG. 3.

### DETAILED DESCRIPTION

Various embodiments of the present disclosure are directed to technology for preventing or mitigating deterioration of elements constituting a word line driving circuit.

According to embodiments of the present disclosure, it is possible to prevent or mitigate deterioration of elements constituting a word line driving circuit.

Hereinafter, various embodiments according to the technical spirit of the present disclosure are described below with reference to the accompanying drawings.

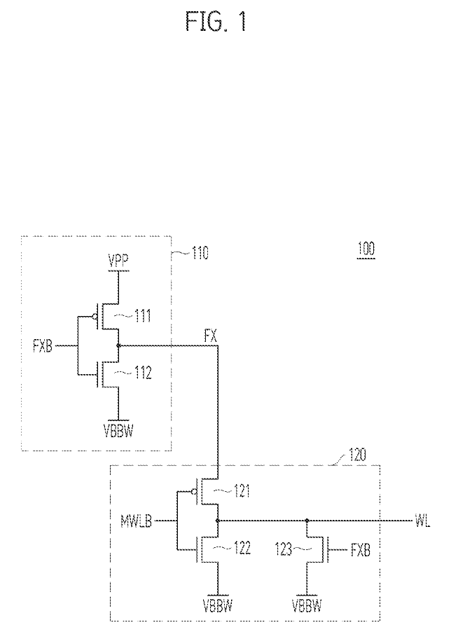

FIG. 1 is a configuration diagram illustrating a word line driving circuit 100 in accordance with an embodiment of the present disclosure.

Referring to FIG. 1, the word line driving circuit 100 includes an auxiliary driver 110 and a main driver 120. FIG. 1 illustrates only the configurations related to driving one word line WL in the word line driving circuit 100.

The auxiliary driver 110 supplies one of a high voltage VPP and a low voltage VBBW to a word line activation voltage terminal FX in response to an auxiliary selection signal FXB. The auxiliary driver 110 may supply the high voltage VPP to the word line activation voltage terminal FX when the auxiliary selection signal FXB is activated at a low level, and may apply the low voltage VBBW to the word line activation voltage terminal FX when the auxiliary selection signal FXB is deactivated at a high level. The auxiliary driver 110 may include a PMOS transistor 111 that drives the word line activation voltage terminal FX with the high voltage VPP in response to the auxiliary selection signal FXB, and an NMOS transistor 112 that drives the word line activation voltage terminal FX with the low voltage VBBW in response to the auxiliary selection signal FXB.

The high voltage VPP is a voltage level for activating the word line WL. The high voltage VPP having a higher level than a power voltage VDD may be generated and used by pumping the power voltage VDD supplied from outside a semiconductor memory device. The low voltage VBBW is a voltage level for deactivating the word line WL. A ground voltage VSS is used as the low voltage VBBW. A negative voltage having a lower level than the ground voltage VSS may be generated through voltage pumping and used as the low voltage VBBW.

The main driver 120 drives the word line WL with one of a voltage of the word line activation voltage terminal FX and the low voltage VBBW in response to a main selection signal MWLB, and drives the word line WL with the low voltage VBBW in response to the auxiliary selection signal FXB. When the main selection signal MWLB is activated at a low level, the main driver 120 may drive the word line WL with the voltage of the word line activation voltage terminal FX, and when the main selection signal MWLB is deactivated at a high level, the main driver 120 may drive the word line WL with the low voltage VBBW. In addition, when the auxiliary selection signal FXB is deactivated at a high level, the main driver 120 may drive the word line WL with the low voltage VBBW. The main driver 120 may include a PMOS transistor 121 that drives the word line WL with the voltage of the word line activation voltage terminal FX in response to the main selection signal MWLB, an NMOS transistor 122 that drives the word line WL with the low voltage VBBW in response to the main selection signal MWLB, and an NMOS transistor 123 that drives the word line WL with low voltage VBBW in response to the auxiliary selection signal FXB.

The word line WL may be activated at a level of the high voltage VPP when the main selection signal MWLB is activated at a low level and the auxiliary selection signal FXB is activated at a low level. The word line WL may be deactivated at a level of the low voltage VBBW when at least one of the main selection signal MWLB and the auxiliary selection signal FXB is deactivated at a high level.

During operation of the semiconductor memory device, an operation of activating the word line WL at the high voltage VPP and then deactivating the word line WL at the low voltage VBBW may be repeatedly performed, and this repeated operation may cause Hot Carrier Injection (HCI) deterioration in the NMOS transistors 122 and 123. When the NMOS transistors 122 and 123 deteriorate, a threshold voltage may increase, a drain current may decrease, and switching speed may decrease. As a result, a transition time that the word line WL transitions from the high voltage VPP to the low voltage VBBW may increase, which may lengthen pre-charge operation time. An increase in the pre-charge operation time may result in a degradation of memory performance. In particular, the greater a drain-source voltage VDS of the NMOS transistors 122 and 123, the more severe the HCI deterioration may be.

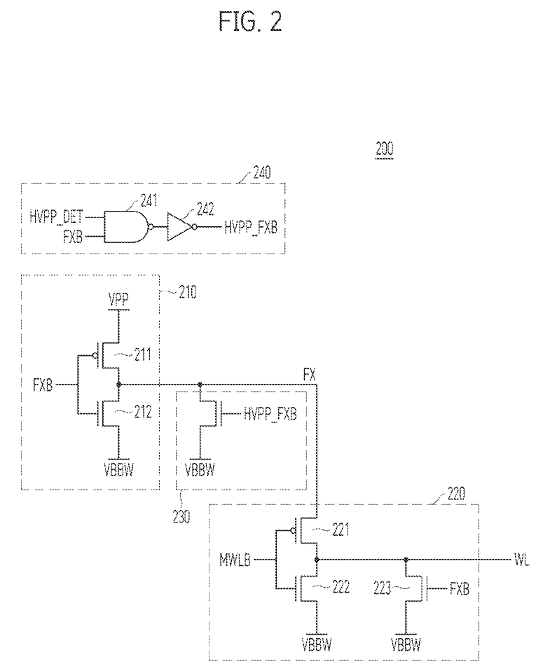

FIG. 2 is a configuration diagram illustrating a word line driving circuit 200 in accordance with an embodiment of the present disclosure.

Referring to FIG. 2, the word line driving circuit 200 includes an auxiliary driver 210, a main driver 220, a voltage discharger 230, and a high voltage auxiliary selection signal generator 240. FIG. 2 illustrates only the configurations related to driving one word line WL in the word line driving circuit 200.

The auxiliary driver 210 supplies one of a high voltage VPP and a low voltage VBBW to a word line activation voltage terminal FX in response to an auxiliary selection signal FXB. When the auxiliary selection signal FXB is activated at a low level, the auxiliary driver 210 may supply the high voltage VPP to the word line activation voltage terminal FX, and when the auxiliary selection signal FXB is deactivated at a high level, the auxiliary driver 210 may apply the low voltage VBBW to the word line activation voltage terminal FX. The auxiliary driver 210 may include a PMOS transistor 211 that drives the word line activation voltage terminal FX with the high voltage VPP in response to the auxiliary selection signal FXB and an NMOS transistor 212 that drives the word line activation voltage terminal FX with the low voltage VBBW in response to the auxiliary selection signal FXB.

The main driver 220 drives the word line WL with one of a voltage of the word line activation voltage terminal FX and the low voltage VBBW in response to a main selection signal MWLB, and drives the word line WL with the low voltage VBBW in response to the auxiliary selection signal FXB. When the main selection signal MWLB is activated at a low level, the main driver 220 may drive the word line WL with the voltage of the word line activation voltage terminal FX, and when the main selection signal MWLB is deactivated at a high level, the main driver 220 may drive the word line WL with the low voltage VBBW. In addition, when the auxiliary selection signal FXB is deactivated at a high level, the main driver 220 may drive the word line WL with the low voltage VBBW. The main driver 220 may include a PMOS transistor 221 that drives the word line WL with the voltage of the word line activation voltage terminal FX in response to the main selection signal MWLB, an NMOS transistor 222 that drives the word line WL with the low voltage VBBW in response to the main selection signal MWLB, and an NMOS transistor 223 that drives the word line WL with the low voltage VBBW in response to the auxiliary selection signal FXB.

The high voltage auxiliary selection signal generator 240 generates a high voltage auxiliary selection signal HVPP_FXB using a high voltage detection signal HVPP_DET and the auxiliary selection signal FXB. The high voltage detection signal HVPP_DET is a signal that is activated at a high level when a level of the high voltage VPP is higher than a reference value. When the high voltage detection signal HVPP_DET is activated at the high level, the high voltage auxiliary selection signal generator 240 may generate the high voltage auxiliary selection signal HVPP_FXB at the same level as the auxiliary selection signal FXB. In addition, when the high voltage detection signal HVPP_DET is deactivated at a low level, the high voltage auxiliary selection signal HVPP_FXB may be fixed to a low level. The high voltage auxiliary selection signal generator 240 may include a NAND gate 241 that receives the high voltage detection signal HVPP_DET and the auxiliary selection signal FXB and an inverter 242 that inverts output of the NAND gate 241 and outputs the inverted signal as the high voltage auxiliary selection signal HVPP_FXB.

The voltage discharger 230 may drive the word line activation voltage terminal FX with the low voltage VBBW in response to the high voltage auxiliary selection signal HVPP_FXB. The voltage discharger 230 may include an NMOS transistor that drives the word line activation voltage terminal FX with the low voltage VBBW in response to the high voltage auxiliary selection signal HVPP_FXB.

When the level of the high voltage VPP is equal to higher than the reference value and the word line WL is deactivated, the voltage discharger 230 is activated to operate so that a voltage level of the word line activation voltage terminal FX may decrease quicker. Accordingly, in an embodiment, a drain-source voltage VDS having a high level is prevented from being applied to the NMOS transistors 222 and 223 of the main driver 220, and as a result, deterioration of the NMOS transistors 222 and 223 may be prevented or mitigated. In an embodiment, when the level of the high voltage VPP is not higher than the reference value, the NMOS transistors 222 and 223 do not deteriorate, and rather, there is a concern that pre-charge operation time may become excessively short due to the operation of the voltage discharger 230. Accordingly, in an embodiment, the voltage discharger 230 may operate only when the level of the high voltage VPP is equal to higher than the reference value.

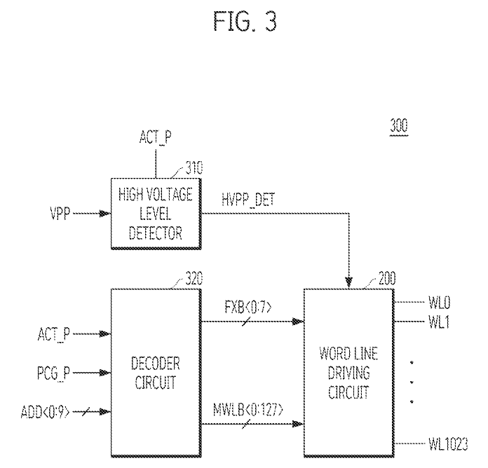

FIG. 3 is a configuration diagram illustrating a semiconductor memory device 300 in accordance with an embodiment of the present disclosure. FIG. 3 illustrates the configurations related to driving word lines WL0 to WL1023 in the semiconductor memory device 300.

Referring to FIG. 3, the semiconductor memory device 300 includes a high voltage level detector 310, a decoder circuit 320, and a word line driving circuit 200.

The high voltage level detector 310 detects a level of a high voltage VPP. The level of the high voltage VPP may vary depending on various conditions, such as a change in a level of a power voltage input from outside the semiconductor memory device 300 and a temperature inside the semiconductor memory device 300. The high voltage level detector 310 may detect whether the level of the high voltage VPP is higher than a reference value and generate a high voltage detection signal HVPP_DET. High voltage level detection time of the high voltage level detector 310 may be when an active pulse signal ACT_P is activated, that is, when an active operation is performed.

The decoder circuit 320 may decode addresses ADD<0:9> and generate main selection signals MWLB<0:127> and auxiliary selection signals FXB<0:7>. The decoder circuit 320 may decode some bits (e.g., 7 bits) of the addresses ADD<0:9> and select one of 128 (=2^7) main selection signals MWLB<0:127>, and may decode the other bits (e.g., 3 bits) of the addresses ADD<0:9> and select one of 8 (=2^3) auxiliary selection signals FXB<0:7>. The selected signal of the main selection signals MWLB<0:127> and the selected signal of the auxiliary selection signals FXB<0:7> may be activated at a low level in response to the activation of the active pulse signal ACT_P. In addition, the signals activated during the activation of the active pulse signal ACT_P may be deactivated at a high level in response to activation of a pre-charge pulse signal PCG_P.

The active pulse signal ACT_P may be a pulse signal that is activated when the active operation of the semiconductor memory device 300 is instructed, and the pre-charge pulse signal PCG_P may be a pulse signal that is activated when a pre-charge operation of the semiconductor memory device 300 is instructed. Because a refresh operation of the semiconductor memory device 300 includes the active operation and the pre-charge operation, the pre-charge pulse signal PCG_P may be activated after the active pulse signal ACT_P is activated even during the refresh operation.

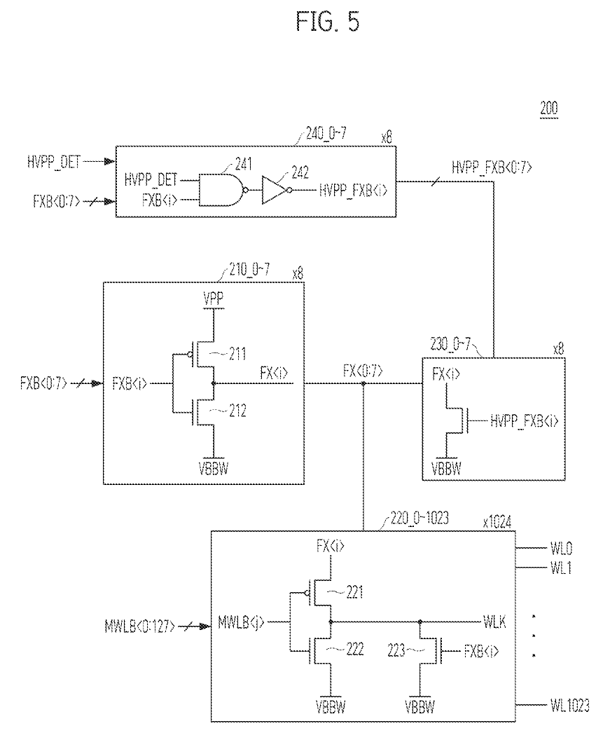

The word line driving circuit 200 may drive the word lines WL0 to WL1023 using the high voltage detection signal HVPP_DET, the main selection signals MWLB<0:127> and the auxiliary selection signals FXB<0:7>. The word line driving circuit 200 activates one of the word lines WL0 to WL1023 during the active operation and deactivates the activated word line during the pre-charge operation. Because a quantity of the main selection signals MWLB<0:127> is 128 and a quantity of the auxiliary selection signals FXB<0:7> is 8, one of 1024 (=128*8) word lines WL0 to WL1023 may be selected. FIG. 2 illustrates only the configurations related to driving one word line in the word line driving circuit 200, but FIG. 5 illustrates in detail how the word line driving circuit 200 that drives a plurality of word lines WL0 to WL1024 is configured.

In FIG. 3, it is exemplified that the addresses ADD<0:9> have 10 bits, the quantity of the main selection signals MWLB<0:127> is 128, the quantity of the auxiliary selection signals FXB<0:7> is 8, and a quantity of the word lines WL0 to WL1023 is 1024. These numbers are only examples and may be changed at any time depending on design.

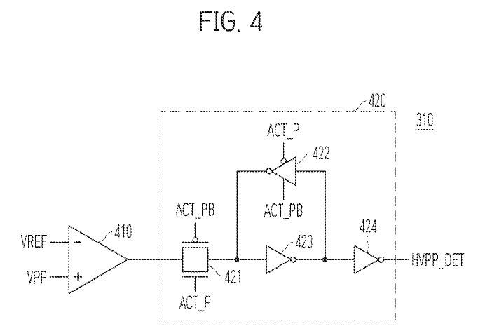

FIG. 4 is a configuration diagram illustrating an example of the high voltage level detector 310 illustrated in FIG. 3.

Referring to FIG. 4, the high voltage level detector 310 includes a comparator 410 and a latch circuit 420.

The comparator 410 compares the level of the high voltage VPP with a level of a reference voltage VREF. The comparator 410 may output an output signal at a high level when the level of the high voltage VPP is higher than the level of the reference voltage VREF, and may output the output signal at a low level when the level of the high voltage VPP is lower than the level of the reference voltage VREF. Herein, it is exemplified that the high voltage VPP is directly compared with the reference voltage VREF, but according to an embodiment, a voltage obtained by dividing the high voltage VPP may be compared with the reference voltage VREF. For example, instead of comparing the high voltage VPP with the reference voltage VREF having 4 V, the comparator 410 may compare a voltage obtained by dividing the high voltage VPP by half (VPP/2) with the reference voltage VREF having 2 V.

The latch circuit 420 may receive the output signal of the comparator 410 during a period in which the active pulse signal ACT_P is activated at a high level, and may output the input signal as the high voltage detection signal HVPP_DET by maintaining a level of the input signal during a period in which the active pulse signal ACT_P is deactivated at a low level. Accordingly, the high voltage detection signal HVPP_DET may be updated whenever the active pulse signal ACT_P is activated. The latch circuit 420 may include a pass gate 421, a tri-state inverter 422, and inverters 423 and 424. Reference symbol “ACT_PB” in the drawing may be an inverted signal of the active pulse signal ACT_P.

FIG. 5 is a configuration diagram illustrating an example of the word line driving circuit 500 illustrated in FIG. 3.

Referring to FIG. 5, the word line driving circuit 500 includes high voltage auxiliary selection signal generators 240_0~7, auxiliary drivers 210_0~7, voltage dischargers 230_0~7, and main drivers 220_0~1023. As used herein, the tilde “~” indicates a range of components. For example, “240_0~7” indicates the high voltage auxiliary selection signal generators 240_0, 240_1, …, and 240_7 shown in FIG. 5.

The high voltage auxiliary selection signal generators 240_0~7, the auxiliary drivers 210_0~7 and the voltage dischargers 230_0~7 may be provided in a quantity of the auxiliary selection signals FXB<0:7>.

The high voltage auxiliary selection signal generators 240_0~7 may generate high voltage auxiliary selection signals HVPP_FXB<0:7> using the high voltage detection signal HVPP_DET and the auxiliary selection signals FXB<0:7>. “i” of reference symbols in the drawing may be an integer from 0 to 7.

The auxiliary drivers 210_0~7 may supply one of the high voltage VPP and low voltage VBBW to word line activation voltage terminals FX<0:7> in response to the auxiliary selection signals FXB<0:7>.

The voltage dischargers 230_0~7 may drive the word line activation voltage terminals FX<0:7> with the low voltage VBBW in response to the high voltage auxiliary selection signals HVPP_FXB<0:7>.

The main drivers 220_0~1023 may be provided as many as a quantity of the word lines WL0 to WL1023. The main drivers 220_0~1023 may drive the word lines WL0 to WL1023 by a combination of the main selection signals MWLB<0:127> and the word line activation voltage terminals FX<0:7>. Because a quantity of the main word line signals MWLB<0:127> is 128, and a quantity of the word line activation voltage terminals FX<0:7> is 8, 1024 (=128*8) word lines WL0 to WL1023 may be driven. “j” of reference symbol “MWLB<j>” in the drawing may be an integer from 0 to 128, and “k” may be an integer from 0 to 1023.

Although the technical spirit of the present disclosure has been described above according to embodiments, this is only for explaining the embodiments according to the concept of the present disclosure, and the present disclosure is not limited to the above embodiments. Various embodiments may be applied by those skilled in the art, to which the present disclosure pertains, within the scope of the technical spirit of the present disclosure.

What is claimed is:

1. A word line driving circuit comprising:
an auxiliary driver configured to supply one of a high voltage and a low voltage to a word line activation voltage terminal in response to an auxiliary selection signal;
a main driver configured to drive a word line with one of a voltage of the word line activation voltage terminal and the low voltage in response to a main selection signal and drive the word line with the low voltage in response to the auxiliary selection signal; and
a voltage discharger configured to drive the word line activation voltage terminal with the low voltage in response to the auxiliary selection signal when a level of the high voltage is determined to be higher than a reference value.

2. The word line driving circuit of claim 1, the auxiliary driver includes:
a first PMOS transistor configured to drive the word line activation voltage terminal with the high voltage in response to the auxiliary selection signal; and
a first NMOS transistor configured to drive the word line activation voltage terminal with the low voltage in response to the auxiliary selection signal.

3. The word line driving circuit of claim 2, wherein the voltage discharger includes a second NMOS transistor configured to drive the word line activation voltage terminal with the low voltage in response to a high voltage auxiliary selection signal having the same level as the auxiliary selection signal, when the level of the high voltage is determined to be higher than the reference value.

4. The word line driving circuit of claim 3, wherein the main driver includes:
a second PMOS transistor configured to drive the word line with the voltage of the word line activation voltage terminal in response to the main selection signal;
a third NMOS transistor configured to drive the word line with the low voltage in response to the main selection signal; and
a fourth NMOS transistor configured to drive the word line with the low voltage in response to the auxiliary selection signal.

5. The word line driving circuit of claim 1, wherein the determination that the level of the high voltage is higher than the reference value is performed during an active operation.

6. A semiconductor memory device comprising:
a high voltage level detector configured to detect when a level of a high voltage is higher than a reference value during an active operation;
a decoder circuit configured to decode an address and generate a plurality of main selection signals and a plurality of auxiliary selection signals; and
a word line driving circuit configured to drive a plurality of word lines according to the plurality of main selection signals, the plurality of auxiliary selection signals and a detection result of the high voltage level detector.

7. The semiconductor memory device of claim 6, wherein the word line driving circuit includes:
a plurality of high voltage auxiliary selection signal generators each configured to generate a corresponding high voltage auxiliary selection signal using a corresponding auxiliary selection signal and a high voltage detection signal;
a plurality of auxiliary drivers each configured to supply one of the high voltage and a low voltage to a corresponding word line activation voltage terminal in response to a corresponding auxiliary selection signal;
a plurality of main drivers each configured to drive a corresponding word line with one of a voltage of a corresponding word line activation voltage terminal and the low voltage in response to a corresponding main selection signal and drive the corresponding word line with the low voltage in response to a corresponding auxiliary selection signal; and
a plurality of voltage dischargers each configured to drive a corresponding word line activation voltage terminal with the low voltage in response to a corresponding high voltage auxiliary selection signals.

8. The semiconductor memory device of claim 7, each of the high voltage auxiliary selection signal generators includes:
a NAND gate configured to receive the corresponding auxiliary selection signal and the high voltage detection signal; and
an inverter configured to receive output of the NAND gate and generate the corresponding high voltage auxiliary selection signal.

9. The semiconductor memory device of claim 7, wherein each of the auxiliary drivers includes:
a first PMOS transistor configured to drive the corresponding word line activation voltage terminal with the high voltage in response to the corresponding auxiliary selection signal; and
a first NMOS transistor configured to drive the corresponding word line activation voltage terminal with the low voltage in response to the corresponding auxiliary selection signal.

10. The semiconductor memory device of claim 9, wherein each of the voltage dischargers includes a second NMOS transistor configured to drive the corresponding word line activation voltage terminal with the low voltage in response to the corresponding high voltage auxiliary selection signal.

11. The semiconductor memory device of claim 10, wherein each of the main drivers include:
a second PMOS transistor configured to drive the corresponding word line with the voltage of the corresponding word line activation voltage terminal in response to the corresponding main selection signal;
a third NMOS transistor configured to drive the corresponding word line with the low voltage in response to the corresponding main selection signal; and
a fourth NMOS transistor configured to drive the corresponding word line with the low voltage in response to the corresponding auxiliary selection signal.

12. The semiconductor memory device of claim 6, wherein the high voltage level detector includes:
a comparator configured to compare the level of the high voltage with a level of the reference voltage; and
a latch circuit configured to receive an output signal of the comparator when an active pulse signal is activated and output an input signal as the detection result by maintaining a level of the input signal during a period in which the active pulse signal is deactivated.

13. The semiconductor memory device of claim 7,
wherein the decoder circuit decodes n bits of the address to generate 2^n of the main selection signals, and decodes the other m bits of the address to generate 2^m of the auxiliary selection signals,
wherein n is a natural number, and
wherein m is a natural number.

14. The semiconductor memory device of claim 13, wherein a quantity of the high voltage auxiliary selection signal generators is 2^m, a quantity of the auxiliary drivers is 2^m, a quantity of the voltage dischargers is 2^m, and a quantity of the main drivers is 2^n * 2^m.
